(19) United States
(12) Patent Application Publication
(10) Pub. No.: US 2024/0014308 A1
(43) Pub. Date: Jan. 11, 2024

(54) A DIE SEAL RING INCLUDING A TWO DIMENSIONAL ELECTRON GAS REGION

(71) Applicant: Power Integrations, Inc., San Jose, CA (US)

(72) Inventors: Kuo-Chang Robert YANG, Campbell, CA (US); Alexey KUDYMOV, Ringoes, NJ (US); Kamal Raj VARADARAJAN, Fremont, CA (US); Alexei ANKOUDINOV, San Jose, CA (US); Sorin S. GEORGESCU, Gilroy, CA (US)

(73) Assignee: Power Integrations, Inc., San Jose, CA (US)

(21) Appl. No.: 18/042,914

(22) PCT Filed: Aug. 27, 2021
(86) PCT No.: PCT/US2021/047836

§ 371 Date: Feb. 24, 2023

Related U.S. Application Data
(60) Provisional application No. 63/073,062, filed on Sep. 1, 2020.

(51) Int. Cl. H01L 29/778; H01L 29/20; H01L 29/417; H01L 29/06

(52) U.S. Cl. CPC H01L 29/7786; H01L 29/2003; H01L 29/41758; H01L 29/0619

(57) ABSTRACT

A die seal ring including a two-dimensional electron gas is presented herein. A semiconductor device comprises an active device region. The active device region comprises a device terminal; and a die seal ring comprising a two dimensional electron gas region surrounds the active device region. By electrically coupling the device terminal to the two dimensional electron gas region, voltages at the semiconductor sidewall may be controlled to substantially equal that of the device terminal.

### CROSS-REFERENCE TO RELATED APPLICATIONS

This application claims the benefit of U.S. Provisional Application No. 63/073,062 filed on Sep. 1, 2020, incorporated in its entirety herein by reference.

### FIELD OF DISCLOSURE

The present disclosure relates generally to die seal ring, and more specifically to a die seal ring including a two dimensional electron gas region.

### BACKGROUND INFORMATION

Gallium nitride (GaN) and other wide band-gap Group III Nitride based direct transitional semiconductor materials exhibit high break-down electric fields and avail high current densities. In this regard GaN based semiconductor devices are actively researched as an alternative to silicon based semiconductor devices in power and high frequency applications. For instance, a GaN high electron mobility transistor (HEMT) may provide lower specific on resistance with higher breakdown voltage relative to a silicon power field effect transistor of commensurate area.

Power field effect transistors (FETs) can be enhancement mode or depletion mode. An enhancement mode device may refer to a transistor (e.g., a field effect transistor) which blocks current (i.e., which is off) when there is no applied gate bias (i.e., when the gate to source bias is zero). In contrast, a depletion mode device may refer to a transistor which allows current (i.e., which is on) when the gate to source bias is zero.

Integrated circuits and power FETs typically use a seal ring. The seal ring is formed at the periphery of the semiconductor die adjacent to the scribe line.

### BRIEF DESCRIPTION OF THE DRAWINGS

Non-limiting and non-exhaustive embodiments of a die seal ring including a two dimensional electron gas (2DEG) region are described with reference to the following figures, wherein like reference numerals refer to like parts throughout the various views unless otherwise specified.

FIG. 1 illustrates a top view of a semiconductor device with a die seal ring according to an embodiment.

FIG. 2A illustrates a cross section of the die seal ring according to the embodiment of FIG. 1.

FIG. 2B illustrates a cross section of the die seal ring extension according to the embodiment of FIG. 1.

FIG. 3A illustrates a cross section of the two dimensional electron gas region.

FIG. 3B illustrates a one dimensional conduction band diagram corresponding with the cross section of FIG. 3A.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements and layers in the figures may be exaggerated relative to other elements to help to improve understanding of various embodiments of the teachings herein. Also, common but well-understood elements, layers, and/or process steps that are useful or necessary in a commercially feasible embodiment are often nit depicted in order to facilitate a less obstructed view of these various embodiments of a die seal ring including a two dimensional electron gas region.

### DETAILED DESCRIPTION

In the following description, numerous specific details are set forth in order to provide a thorough understanding of a die seal ring including a two dimensional electron gas region. It will be apparent, however, to one having ordinary skill in the art that the specific detail need not be employed to practice the teachings herein. In other instances, well-known materials or methods have not been described in detail in order to avoid obscuring the present disclosure.

Reference throughout this specification to “one embodiment”, “an embodiment”. “one example” or “an example” means that a particular feature, structure, method, process, and/or characteristic described in connection with the embodiment or example is included in at least one embodiment of a die seal ring including a two dimensional electron gas region. Thus, appearances of the phrases “in one embodiment”, “in an embodiment”. “one example” or “an example” in various places throughout this specification are not necessarily all referring to the same embodiment or example. Furthermore, the particular features, structures, methods, processes and/or characteristics may be combined in any suitable combinations and/or subcombinations in one or more embodiments or examples. In addition, it is appreciated that the figures provided herewith are for explanation purposes to persons ordinarily skilled in the art and that the drawings are not necessarily drawn to scale.

In the context of the present application, when a transistor is in an “off-state” or “off” the transistor blocks current and/or does not substantially conduct current. Conversely, when a transistor is in an “on-state” or “on” the transistor is able to substantially conduct current. Also, for purposes of this disclosure, “ground” or “ground potential” refers to a reference voltage or potential against which all other voltages or potentials of an electronic circuit, device, or Integrated circuit (IC) are defined or measured.

Also in the context of the present application, a power field effect transistor which blocks current while supporting medium to high voltages may also be referred to as a high voltage field effect transistor. For instance, a lateral field effect transistor (FET) may be configured to block current with a high drain to source voltage. In one application the lateral FET may be an enhancement mode field effect transistor, and the lateral FET may be configured to block current while a gate to source voltage is less than a positive threshold voltage. For instance, an enhancement mode field effect transistor may be configured to block current while supporting a high drain to source voltage (e.g., seven hundred volts) when the gate to source voltage is substantially equal to zero volts.

In another application the lateral FET may be a depletion mode field effect transistor, and the lateral FET may be electrically coupled in cascode with an enhancement mode field effect transistor. Coupled in cascode the depletion mode lateral FET may also block current and support medium to high voltages, while the enhancement mode transistor operates in the off state. Coupled in cascode the depletion mode lateral FET may block current while supporting a high drain to source voltage (e.g., seven hundred volts) because its gate to source voltage may be forced to a negative voltage (e.g., negative twenty volts), less than a depletion mode threshold.

Unfortunately, high drain to source voltages in a semiconductor device may lead to reliability failure. For instance, when a high voltage extends toward the edge of the die, sometimes referred to as the sidewall, of a semiconductor device, the high voltage may attract moisture, ions, and/or other contaminants from either the air or packaging compounds (e.g., molding compound). Moreover, traditional seal rings with surface field plates prove ineffective in reducing the extension of high voltage towards the sidewall in a GaN based semiconductor, accordingly, there is a need to develop a seal ring for GaN based semiconductor devices.

A die seal ring including a two-dimensional electron gas is presented herein. A semiconductor device comprises an active device region. The active device region comprises a device terminal; and a die seal ring comprising a two dimensional electron gas region surrounds the active device region. By electrically coupling the device terminal to the two dimensional electron gas region, voltages at the semiconductor sidewall may be controlled to substantially equal that of the device terminal.

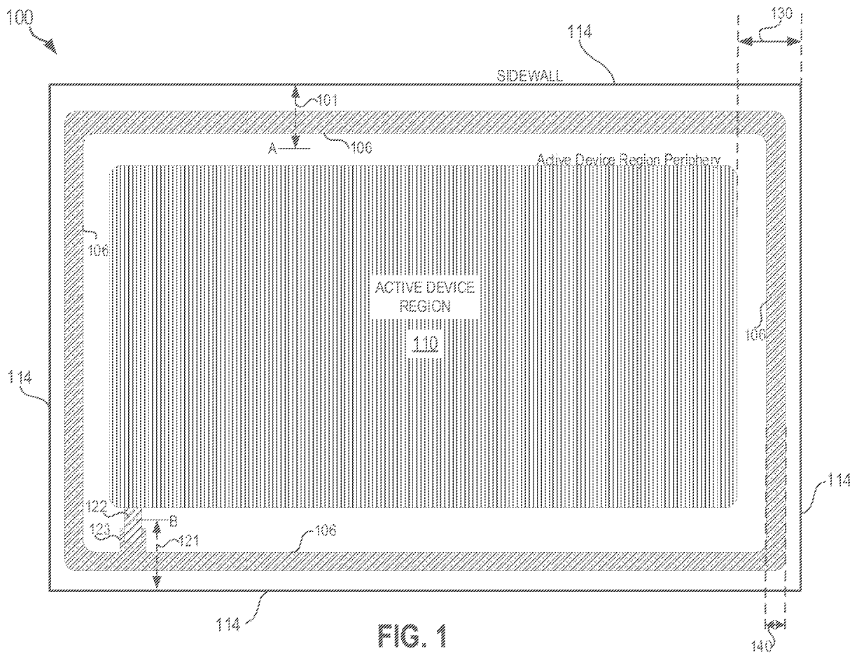

FIG. 1 illustrates a top view of a semiconductor device 100 with a die seal ring 106 according to an embodiment. The semiconductor device 100 also comprises an active device region 110. As illustrated the die seal ring 106 may be near the sidewall 114 of the semiconductor device 100 and may surround the active device region 110.

The active device region 110 may be an active transistor region. For instance, the active device region 110 may comprise a lateral high electron mobility transistor (HEMT) or high voltage (power) field effect transistor (FET). As discussed above, power FETs may be GaN based to advantageously offer improved medium to high voltage performance. For instance, a lateral FET comprising a heterostructure formed between layers of gallium nitride (GaN) and aluminum gallium nitride (AlGaN), may be used for medium to high voltage applications (e.g., voltages between two hundred volts (200V) and one-thousand two-hundred volts (120V)).

Additionally, the active device region 110 may include a lateral FET which comprises active device terminals (e.g., source, gate, and drain terminals). In one embodiment the active device terminals may be formed using stripes. According to the teachings herein the die seal ring 106 may include a two dimensional electron gas region to mitigate high voltages which extend from the active device region toward the sidewall 114.

For instance, during the off state when a drain terminal (e.g., a drain stripe) has a high voltage, the high voltage may be near the active device region periphery. As illustrated, a die seal ring extension 123 may extend from the die seal ring 106 to avail an electrical connection with a device terminal 122. By electrically connecting the two dimensional electron gas to the device terminal 122 (e.g., a source or gate terminal), a voltage of the two dimensional electron gas may become substantially equal to that of the device terminal 122.

Accordingly, when the voltage of the device terminal 122 is the lowest relative voltage (e.g., ground potential), then the voltage of the die seal ring 106 (i.e., the voltage of the two dimensional electron gas region) may force the sidewall voltage to be substantially equal to that of the device terminal 122. In doing so, the aforementioned high voltage moisture related damage may be reduced or eliminated.

When the semiconductor device 100 is a GaN based semiconductor device, then the two dimensional electron gas region may be availed during the process steps of the active device region 110. For instance, in a GaN based process, the two dimensional electron gas region of the die seal ring 10 and die seal ring extension 123 may be formed using the same or similar process steps of a lateral FET.

In this regard, the die seal ring 106 may have dimension 140 commensurate with that of a gate region in a lateral FET. For instance, dimension 140 may be between five microns and twenty five microns. Also, the die seal ring 106 may be located within a distance 130 from the sidewall. In one application the distance 130 may be between two microns and fifty microns.

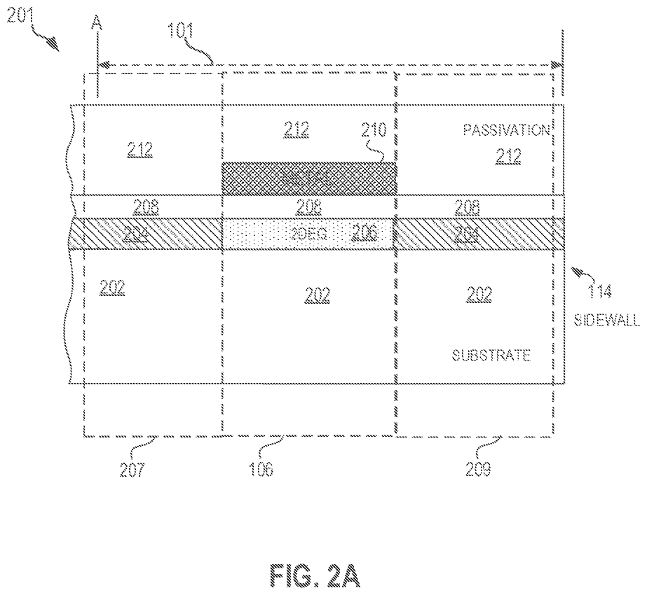

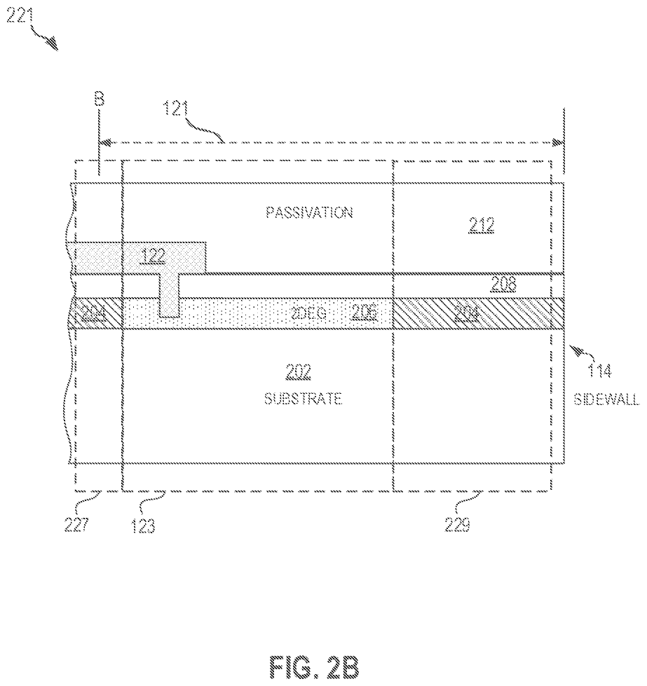

Additionally, as presented below in the discussion of FIG. 2A and FIG. 2B, the die seal ring 106 and the die seal ring extension 123 may be physically (i.e., laterally) isolated from the active device region 110.

FIG. 2A illustrates a cross section 201 corresponding with a segment 101 between of the sidewall 114 and location A of FIG. 1. As illustrated, segment 101 also includes the die seal ring 106. As shown by cross section 201, the die seal ring 106 comprises the following layers: a substrate 202, a two dimensional electron gas (2DEG) region 206, a dielectric 208 (e.g., a lateral FET gate dielectric), a metal 210 (e.g., a lateral FET gate metal), and passivation 212.

Also as shown by cross section 201, adjacent region 207 and adjacent region 209 include the same layers as seal ring 106 except for the metal 210 and the two dimensional electron gas region 206. Instead of having a layer forming the two dimensional electron gas region 206, the adjacent region 207 and adjacent region 209 have insulation layer 204 adjacent to the two dimensional electron gas region 206. Insulation layer 204 may laterally isolate and/or insulate the two dimensional electron gas region 206 from the sidewall 114 and from the active device region 110.

As one of ordinary skill in the art may appreciate, the dimensions of the layers (e.g, the substrate 202 and two dimensional electron gas region 206) may not be to scale. Moreover, some of the layers may not be illustrated for presentation purposes. For instance, some embodiments may include multiple layers of passivation and/or metal layers. In one embodiment the substrate can be silicon or sapphire; and the two dimensional electron gas region 206 may be formed on top of a grown buffer layer (e.g., an epitaxial layer) several microns thick.

Additionally, the insulation layer 204 and the two dimensional electron gas region 206 may include GaN and/or AlGaN having a total thickness between twenty and fifty nanometers. In another embodiment the insulation layer 204 may be created by implanting nitrogen (N) to disrupt the GaN lattice.

FIG. 2B illustrates a cross section 221 corresponding with a segment 121 between the sidewall 114 and location B of FIG. 1. As illustrated, segment 121 also includes the die seal ring extension 123. As shown by cross section 221, the die seal ring extension 123 comprises the same layer as die seal ring 106 except for the metal 210. Instead, the die seal ring extension 123 includes the device terminal 122 which may be an interconnect material such as metal or polysilicon.

Also as illustrated, the device terminal 122 is electrically connected to the two dimensional electron gas region by virtue of an opening (e.g., a via or contact opening) in the dielectric 208.

Additionally, adjacent region 227 includes the same layers as die seal ring extension 123 except for the two dimensional electron gas region 206; and adjacent region 229 includes the same layers as die seal ring extension 123 except for the device terminal 122 and the two dimensional electron gas region 206. Similar to adjacent region 207 and adjacent region 209, adjacent region 227 and adjacent region 229 include insulation layer 204. As discussed above, insulation layer 204 may laterally isolate and/or insulate the two dimensional electron gas region 206 from the sidewall 114 and from the active device region 110.

As discussed above with respect to FIG. 2A, dimensions of the layers may not be to scale; additionally, the number of layers and/or interconnect layers (e.g., metal) may be excluded for presentation purposes. For instance, as described below the two dimensional electron gas region 206 may comprise GaN; additionally, the insulation layer 204 may comprise GaN which has been intentionally damaged by ion implantation.

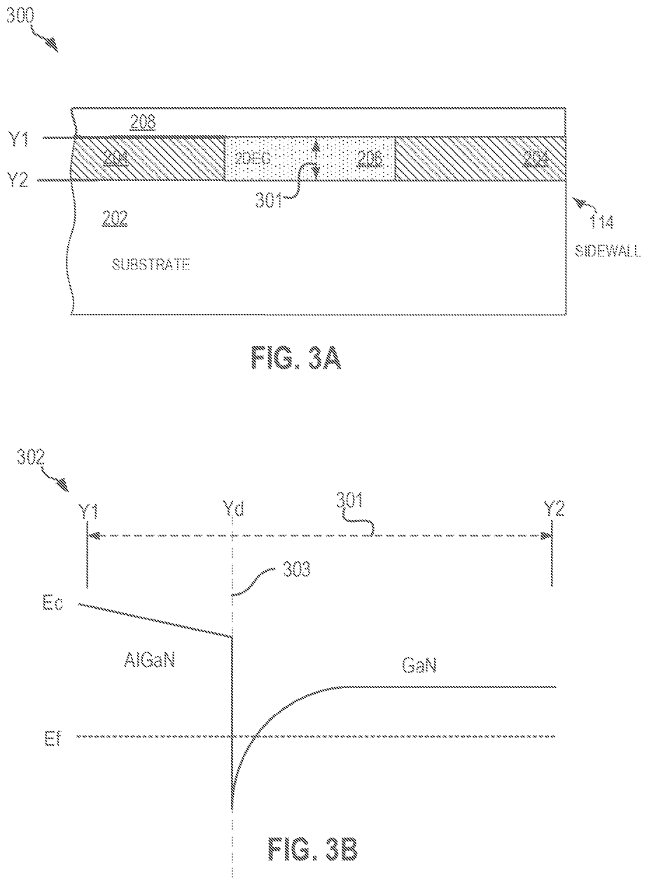

FIG. 3A illustrates a cross section 300 of the two dimensional electron gas region 206. Cross section 300 shows the two dimensional electron gas region 206 laterally isolated by insulator region 204. Cross section 300 shows a line 301 drawn between an interface Y1 and an interface Y2. The dimension of line 301 may correspond with a thickness of the material or layers of materials used to create a heterojunction.

For instance, FIG. 3B illustrates a one dimensional conduction band diagram 302 corresponding with the cross section of FIG. 3A. Conduction band diagram 302 illustrates the conduction band energy Ec as a function of position between interface Y1 and interface Y2 and along line 301. Conduction band diagram 302 also illustrates a discontinuity in the conduction band energy Ec at position Yd. Between interface Y1 and position Yd the two dimensional electron gas region 206 may comprise AlGaN and/or a layer of AlGaN. Between position Yd and interface Y2 the two dimensional electron gas region 206 may comprise GaN and/or a layer of GaN. As one of ordinary skill in the art may appreciate, an electron gas is formed at or near position Yd where the Fermi level Ef is greater than (i.e., is above) the conduction band energy Ec.

The above description of illustrated examples of the present disclosure, including what is described in the Abstract, are not intended to be exhaustive or to be limitation to the precise forms disclosed. While specific embodiments of a die seal ring including a two dimensional electron gas region are described herein for illustrative purposes, various equivalent modifications are possible without departing from the broader spirit and scope of the present disclosure. Indeed, it is appreciated that the specific example device cross sections are provided for explanation purposes and that other embodiments and/or materials (e.g., gallium arsenide and aluminum gallium arsenide) may also be employed in accordance with the teachings herein.

Although the present invention is defined in the claims, it should be understood that the present invention can alternatively be defined in accordance with the following examples:

Example 1: A semiconductor device comprising: an active device region and a die seal ring surrounding the active device region. The die seal ring comprises a two dimensional electron gas region.

Example 2: The semiconductor device of example 1, wherein the active device region comprises a lateral field effect transistor (FET).

Example 3: The semiconductor device of any one of the preceding examples, wherein the lateral field effect transistor is a high electron mobility transistor (HEMT).

Example 4: The semiconductor device of any one of the preceding examples, wherein the two dimensional electron gas region comprises gallium nitride (GaN).

Example 5: The semiconductor device of any one of the preceding examples, wherein the two dimensional electron gas region is laterally separated from the active device region.

Example 6: The semiconductor device of any one of the preceding examples, further comprising an insulator region.

Example 7: The semiconductor device of any one of the preceding examples, wherein the insulator region comprises gallium nitride (GaN).

Example 8: The semiconductor device of any one of the preceding examples, wherein the insulator region is formed using ion implantation.

Example 9: The semiconductor device of any one of the preceding examples, wherein the two dimensional electron gas region is electrically coupled to the device terminal.

Example 10: The semiconductor device of any one of the preceding examples, wherein the two dimensional electron gas region is configured to receive an electric potential of the device terminal.

Example 11: The semiconductor device of any one of the preceding examples, wherein the device terminal is a gate terminal.

Example 12: The semiconductor device of any one of the preceding examples, wherein the device terminal is a source terminal.

Example 13: The semiconductor device of any one of the preceding examples, wherein the electric potential of the device terminal is substantially equal to zero volts.

Example 14: A power field effect transistor (FET) comprising: an active device region and a die seal ring. The die seal ring surrounds the active device region along a periphery of the power FET; and the die seal ring comprises a two dimensional electron gas region.

Example 15: The power FET of any one of the preceding examples, wherein the active device region comprises: a drain terminal configured to receive a drain voltage; a gate terminal configured to receive a gate voltage; and a source terminal configured to receive a source voltage.

Example 16: The power FET of any one of the preceding examples, wherein the two dimensional electron gas region is electrically coupled to the gate terminal.

Example 17: The power FET of any one of the preceding examples, wherein the two dimensional electron gas region is electrically coupled to the source terminal.

Example 18: The power FET of any one of the preceding examples, wherein the two dimensional electron gas region is configured to receive a voltage substantially equal to zero volts.

Example 19: The power FET of any one of the preceding examples, the power FET configured to block a high voltage.

Example 20: The power FET of any one of the preceding examples, the power FET configured to switch a high voltage.

1. A semiconductor device comprising:
an active device region comprising a device terminal; and
a die seal ring surrounding the active device region, the die seal ring comprising a two dimensional electron gas region electrically coupled to a gate terminal.

2. The semiconductor device of claim 1, wherein the active device region comprises a lateral field effect transistor (FET).

3. The semiconductor device of claim 2, wherein the lateral field effect transistor is a high electron mobility transistor (HEMT).

4. The semiconductor device of claim 3, wherein the two dimensional electron gas region comprises gallium nitride (GaN).

5. The semiconductor device of claim 1, wherein the two dimensional electron gas region is laterally separated from the active device region.

6. The semiconductor device of claim 1 further comprising an insulator region.

7. The semiconductor device of claim 6, wherein the insulator region comprises gallium nitride (GaN).

8. The semiconductor device of claim 7, wherein the insulator region is formed using ion implantation.

9. (canceled)

10. The semiconductor device of claim 1, wherein the two dimensional electron gas region is configured to receive an electric potential of the device gate terminal.

11. (canceled)

12. (canceled)

13. The semiconductor device of claim 10, wherein the electric potential of the gate terminal is substantially equal to zero volts.

14. A power field effect transistor (FET) comprising:
an active device region; and
a die seal ring surrounding the active device region along a periphery of the power FET, the die seal ring comprising a two dimensional electron gas region electrically coupled to a gate terminal.

15. The power FET of claim 14, wherein the active device region comprises:
a drain terminal configured to receive a drain voltage;
the gate terminal configured to receive a gate voltage; and
a source terminal configured to receive a source voltage.

16. (canceled)

17. (canceled)

18. The power FET of claim 15, wherein the two dimensional electron gas region is configured to receive a voltage substantially equal to zero volts.

19. The power FET of claim 15, the power FET configured to block a high voltage.

20. The power FET of claim 15, the power FET configured to switch a high voltage.
